(19) United States
(12) Patent Application Publication
(10) Pub. No.: US 2013/0341502 A1
(43) Pub. Date: Dec. 26, 2013

(54) METHOD AND APPARATUS FOR TWO POINT CALIBRATION OF A TUNABLE DIODE LASER ANALYZER

(71) Applicants: Alan Cowie, Friendswood, TX (US); Jie Zhu, Pearland, TX (US)

(72) Inventors: Alan Cowie, Friendswood, TX (US); Jie Zhu, Pearland, TX (US)

(21) Appl. No.: 13/986,943

(22) Filed: Jun. 17, 2013

Related U.S. Application Data
(60) Provisional application No. 61/690,281, filed on Jun. 22, 2012.

(51) Int. Cl. G01N 21/27; H01S 5/00

(52) U.S. Cl. CPC G01N 21/274; H01S 5/005
USPC 250/252.1; 359/641

(57) ABSTRACT

An improved method for two point calibration of a tunable diode laser (TDL) spectrometer by the steps of (a) directing a first portion of the light from the TDL through a known gas to a first light detector as the current fed to the TDL is varied so that current values are determined for at least two known absorption peaks of the known gas; (b) while concurrently directing a second portion of the light from the TDL through a gas to be analyzed to a second light detector. In addition, an improved laser module for use in a TDL analyzer, the module defining a cavity therein across which cavity a portion of the light from a TDL is directed to collimation optics for collimating the light from the module wherein the improvement is a gas reference cell positioned at least partially in the cavity so that a portion of the light from the TDL that is not directed to the collimation optics is shown through a gas in the gas reference cell to a light detector.

This application claims priority to U.S. Provisional Patent Application 61/690,281 filed 22 Jun. 2012 and to U.S. Provisional Patent Application 61/690,271 filed 22 Jun. 2012. The instant invention is in the field of gas analysis, such as combustion gas analysis, and more specifically the instant invention is in the field of tunable diode laser spectroscopic analysis of a gas. A tunable diode laser emits near monochromatic light of a wavelength that is dependent on the current fed to the diode. Tunable diode laser spectroscopic analysis of combustion gases is known and described in the prior art, for example, by: Lackner et al., Thermal Science, V.6, p 13-27, 2002; Allen, Measurement Science and Technology, V.9, p 545-562, 1998; Nikkary et al., Applied Optics, V.41(3), p 446-452, 2002; Upschulte et al., Applied Optics, V.38(9), p 1506-1512, 1999; Mihalcea et al., Measurement Science and Technology, V.9, p 327-338, 1998; Webber et al., Proceedings of the Combustion Institute, V.28, p 407-413, 2000; Ebert et al., Proceedings of the Combustion Institute, V.30, p 1611-1618, 2005; Nagali et al., Applied Optics, V.35(21), p 4027-4032, 1996; and U.S. Pat. Nos. 7,248,755 7,244,936 and 7,217,121.

### BACKGROUND OF THE INVENTION

US Patent Application Publication 2010-0028819 and www.yokogawa.com/us/ia/analytical/tdls200 describe the TruePeak® TDLS200 tunable diode laser spectroscopy analyzer from Yokogawa Corporation of America. FIG. 4 of the '819 publication details the laser and detector system. Referring to said FIG. 4 of the '819 publication, the tunable diode laser gas analysis system includes a laser module 37 containing the tunable diode laser. A control unit 31 contains the central processing unit (CPU) programmed for signal processing as well as the temperature and current control for the tunable diode laser and a user interface and display. Alignment plate 29 and adjustment rods 30 allow alignment of the laser beam 41. Dual process isolation windows 28 are mounted in a pipe flange 40. The space between the windows 28 is preferably purged with nitrogen. In this specific example, the flange 40 is mounted through the wall of a furnace.

The laser beam 41 is passed through the combustion gas of the furnace and then through dual process isolation windows 33 to a near infrared light detector 38. The windows 33 are mounted in a pipe flange 39. The space between the windows 33 is preferably purged with nitrogen. The flange 39 is mounted through the wall of the furnace. Alignment plate 34 and adjustment rods 35 allow alignment of the detector optics with the laser beam 41. Detector electronics 36 are in electrical communication with the control unit 31 by way of cable 37a. The control unit 31 is also in electrical communication (by way of electrical cables 38a) with a process control system 32 for controlling the furnace 10.

The above described system of the '819 publication is broadly applicable to the analysis of any gas and operates by measuring the amount of laser light at specific wavelengths, which light is absorbed (lost) as it travels through the gas. For example, when the gas is combustion gas, carbon monoxide, gaseous water and hydrocarbons each have a spectral absorption of infrared light that exhibits unique fine structure. The individual features of the spectra are seen at the high resolution of the tunable diode laser.

The system described above is commercially successful and is used, for example, to optimize the operation of furnaces in oil refineries. However, problems remain with such systems. For example, the precise wavelength of the diode at a specific precise current fed to the diode and the slope of wavelength from the diode v. current fed to the diode can drift in time and with temperature, thereby complicating system calibration. Ideally, all diodes of a given specification would emit the same wavelength at the same current and would have the same slope of wavelength v. current. In practice they differ somewhat when new and drift as they age.

U.S. Pat. No. 5,572,031 discloses a tunable diode laser oxygen analyzer employing a reference cell containing oxygen to calibrate the analyzer and to lock the tunable diode laser to a specific oxygen absorption line. U.S. Pat. No. 7,586,613 discloses a tunable diode laser analyzer employing a separate two point calibration (preferably by determining the absorption maxima of two adjacent lines of a calibration gas) including the determination of calibration gas concentration thereby permitting not only the line locking function for two absorption lines but also offset and gain correction over time as the system ages. Despite the advance in the above-mention prior art, it would be an important advance in the art if a two point calibration system were developed that did not require a separate calibration or the determination of the concentration of the calibration gas.

### SUMMARY OF THE INVENTION

The instant invention is a solution to the above-mentioned problem. The instant invention is an improved method for two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies, wherein the improvement comprises the steps of: (a) directing a first portion of the light from the TDL through a known gas to a first light detector as the current fed to the TDL is varied so that current values are determined for at least two known absorption peaks of the known gas; (b) while concurrently directing a second portion of the light from the TDL through a gas to be analyzed to a second light detector.

In another embodiment, the instant invention is an improved laser module for use in a TDL analyzer, the module defining a cavity therein across which cavity light from a TDL is directed to collimation optics for collimating the light from the module, wherein the improvement comprises a gas reference cell positioned at least partially in the cavity so that a portion of the light from the TDL is directed through a gas in the gas reference cell to a light detector.

In yet another embodiment, the instant invention is an improved method for two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies, wherein the improvement comprises the step of directing light from the TDL through a known gas and then through a gas to be analyzed to a light detector as the current fed to the TDL is varied so that current values are determined for at least two known absorption peaks of the known gas.

### BRIEF DESCRIPTION OF THE DRAWINGS

FIG. 1 depicts the raw detector signal from a tunable diode laser analyzer for the 763.73 and 763.84 nanometer lines of oxygen;

FIG. 2 depicts the spectrum of FIG. 1 after conversion of the raw detector signal to absorption units;

FIG. 3 depicts the drift of the 763.73 line for oxygen from the position shown in FIG. 2 to a position at about 200 data points;

FIG. 4 depicts the drift of the 763.73 line for oxygen from the position shown in FIG. 2 to a position at about 250 data points;

FIG. 5 is a side view, part in cross section, part in full, showing a cell filled with a reference gas positioned in a laser module of a tunable diode laser spectroscopy analyzer; and

FIG. 6 is a side view, part in cross section, part in full, showing a cell filled with a reference gas positioned in a different location of a laser module of a tunable diode laser spectroscopy analyzer.

### DETAILED DESCRIPTION

Two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies is known as taught, for example, in U.S. Pat. No. 7,586,613. The instant invention is an improved two point method and apparatus for calibrating a TDL spectrometer. The improvement of the instant invention comprises the steps of: (a) directing a first portion of the light from the TDL through a known gas to a first light detector as the current fed to the TDL is varied so that current values are determined for at least two known absorption peaks of the known gas; (b) while concurrently directing a second portion of the light from the TDL through a gas to be analyzed to a second light detector. In an alternative embodiment, the instant invention is an improved method for two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies, wherein the improvement comprises the step of directing light from the TDL through a known gas and then through a gas to be analyzed to a light detector as the current fed to the TDL is varied so that current values are determined for at least two known absorption peaks of the known gas. The known gas can be positioned in the cavity of a TDL laser module or in a cell positioned in the cavity of a TDL laser module or in a cell positioned in the collimated beam of light emitted from a TDL laser module.

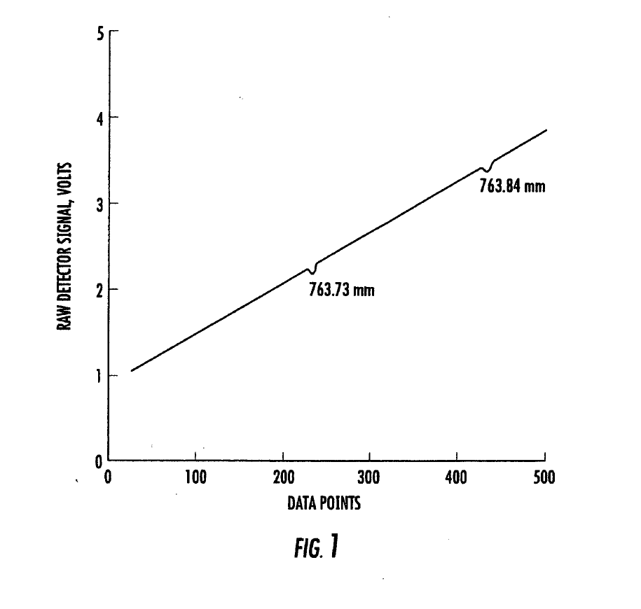

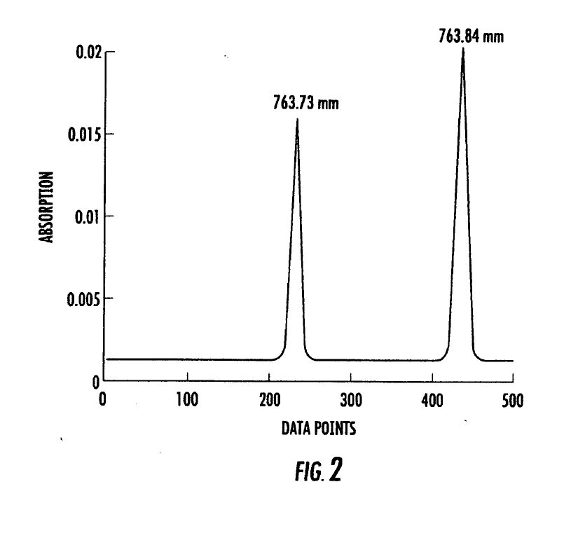

Referring now to FIG. 1, therein is shown a small portion of the raw detector signal from detector of a tunable diode laser analyzer as the current fed to the diode of the diode module is increased in increments from step 0 to step 500 (corresponding to data point 0 to data point 500) for a gas consisting of 22.30% oxygen in nitrogen. The dip in the raw detector signal at 763.73 and 763.84 nanometers wavelength is due to the absorption of the light beam by oxygen. These wavelengths are fixed by natural law. Referring now to FIG. 2, the peaks in FIG. 2 represent the transformation of the raw detector signal of FIG. 1 into absorbance units (au).

The instant invention is not dependent on the concentration of the component present in the reference cell as long as at least two absorption peaks of the component are detected . The above-mentioned 763.73 and 763.84 nanometer wavelengths for oxygen are for example only. The instant invention is not limited to these absorption peak wavelengths or to the analysis of oxygen. It should also be understood that more that two known absorption peaks can be determined in the method of the instant invention.

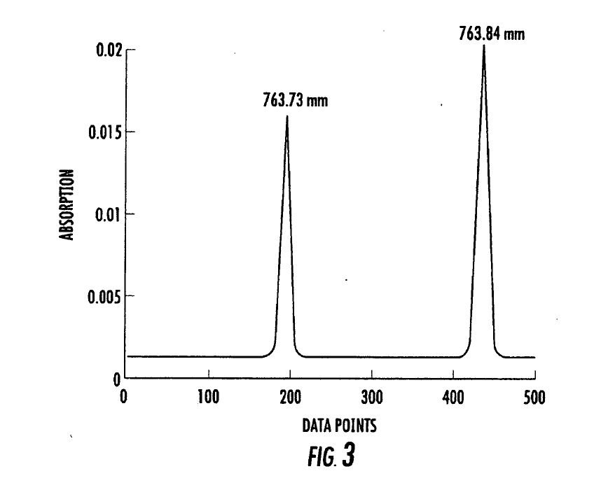

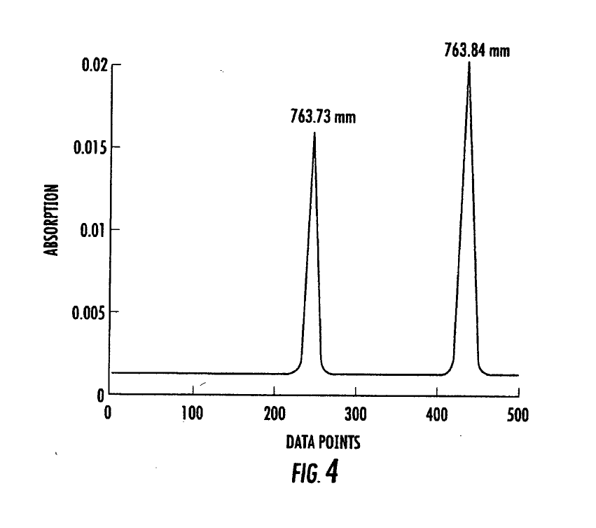

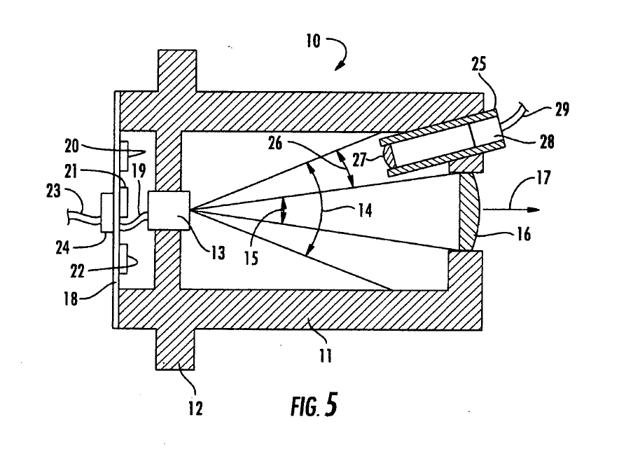

Referring now to FIG. 5, therein is shown one embodiment of a laser module from a TruePeak® TDLS200 TDL spectroscopy analyzer from Yokogawa Corporation of America modified according to the instant invention. The laser module 10 comprises a body 11 having a mounting flange 12. A tunable diode laser 13 is mounted in the body 11 and emits a cone of light 14. A portion 15 of the cone of light 14 is directed to collimation lens 16 to produce a column of light 17 from the collimation lens 16. The tunable diode laser 13 is in electrical communication with circuit board 18 by way of wiring 19. Various electronic components 20, 21 and 22 are mounted on the circuit board 18 and are in electrical communication with cable 23 and connector 24. Cable 23 is in electrical communication with the CPU of the analyzer. The body 11 is bored through to receive an aluminum tube 25 sealed in the body 11 with an epoxy sealant. A positive lens 27 is sealed at one end of the tube 25 using epoxy sealant. The tube is filled with oxygen and then a Hamamatsu S-2386 light detector 28 is sealed at the other end of the tube 25 to form a reference cell filled with oxygen comprised of elements 25, 27 and 28. The light detector 28 is in electrical communication with the CPU of the analyzer by way of cable 29 so that a portion 26 the laser beam that is not directed through the collimation lens 16 of the laser module is directed to the positive lens 27, through the oxygen in the tube 25 and to the light detector 28. The CPU of the analyzer is programmed to determine the data point distance between the oxygen absorption peaks shown in FIG. 1 for the oxygen contained in the tube 25 to provide a two point calibration of the analyzer if the system drifts from the condition shown in FIG. 1 to the condition shown, for example, in FIG. 3 or 4.

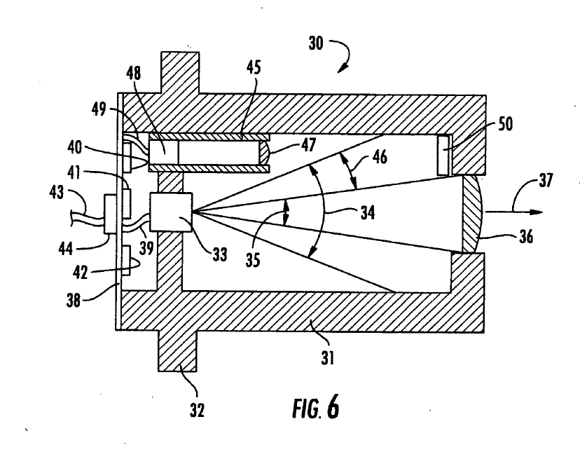

Referring now to FIG. 6, therein is shown another embodiment of a laser module from a TruePeak® TDLS200 TDL spectroscopy analyzer from Yokogawa Corporation of America modified according to the instant invention. The laser module 30 comprises a body 31 having a mounting flange 32. A tunable diode laser 33 is mounted in the body 31 and emits a cone of light 34. A portion 35 of the cone of light 34 is directed to collimation lens 36 to produce a column of light 37 from the collimation lens 36. The tunable diode laser 33 is in electrical communication with circuit board 38 by way of wiring 39. Various electronic components 40, 41 and 42 are mounted on the circuit board 38 and are in electrical communication with cable 43 and connector 44. Cable 43 is in electrical communication with the CPU of the analyzer. The body 31 is bored through to receive an aluminum tube 45 sealed in the body 31 with an epoxy sealant. A positive lens 47 is sealed at one end of the tube 45 using an epoxy sealant. The tube 45 is filled with oxygen and then a Hamamatsu S-2386 light detector 48 is sealed at the other end of the tube 45 to form a reference cell filled with oxygen comprised of elements 45, 47 and 48. The light detector 48 is in electrical communication with the CPU of the analyzer by way of cable 49 and circuit board 38 so that a portion 46 the laser beam that is not directed through the collimation lens 36 of the laser module 30 is reflected from concave mirror 50 and directed to the positive lens 47, through the oxygen in the tube 45 and to the light detector 48. The CPU of the analyzer is programmed to determine the data point distance between the oxygen absorption peaks shown in FIG. 1 for the oxygen contained in the tube 45 to provide a two point calibration of the analyzer if the system drifts from the condition shown in FIG. 1 to the condition shown, for example, in FIG. 3 or 4.

### EXAMPLE

A TruePeak® TDLS200 TDL spectroscopy analyzer from Yokogawa Corporation of America is used to determine the percent oxygen in a sample of air known to consist of 22.30% oxygen in nitrogen. The analyzer reports that the sample contains 22.30% oxygen. The span calibration (i.e., the absorption peak position v. the specific current fed to the TDL) of the analyzer then drifts as shown in FIG. 3 for a sample consisting of 22.30% oxygen in nitrogen. The original position of the peak at 763.73 nanometers has drifted to a position at a lower data point, i.e., at about data point 200 while the peak at 763.84 nanometers remained at the same data point. The analyzer reports that the sample contains 25.50% oxygen. The span calibration (i.e., the absorption peak position v. the specific current fed to the TDL) of the analyzer then drifts as shown in FIG. 4 for a sample consisting of 22.30% oxygen in nitrogen. The original position of the peak at 763.73 nanometers has drifted to a position at a higher data point, i.e., at about data point 250 while the peak at 763.84 nanometers remained at the same data point. The analyzer reports that the sample contains 19.70% oxygen.

The laser module of the analyzer is modified as shown in FIG. 5 as described in detail above. The CPU of the analyzer is programmed to concurrently determine the data point distance between the oxygen absorption peaks shown in FIG. 2 from the detector 28 shown in FIG. 5 to provide a two point calibration of the analyzer as the system drifts as shown in FIGS. 3 and 4. The analyzer is used to determine the concentration of oxygen in air. At the original peak position shown in FIG. 2, the analyzer reports that the air contains 22.30% oxygen. At the peak position shown in FIG. 3 the analyzer reports that the air contains 22.31% oxygen. At the peak position shown in FIG. 4 the analyzer reports that the air contains 22.26% oxygen.

### CONCLUSION

While the instant invention has been described above according to its preferred embodiments, it can be modified within the spirit and scope of this disclosure. This application is therefore intended to cover any variations, uses, or adaptations of the instant invention using the general principles disclosed herein. Further, the instant application is intended to cover such departures from the present disclosure as come within the known or customary practice in the art to which this invention pertains and which fall within the limits of the following claim.

What is claimed is:

1. An improved method for two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies, wherein the improvement comprises the steps of: (a) directing a first portion of the light from the TDL through a known gas to a first light detector as the current fed to the TDL is varied so that current values are determined for at least two known absorption peaks of the known gas; (b) while concurrently directing a second portion of the light from the TDL through a gas to be analyzed to a second light detector.

2. The improved method of claim 1, wherein the known gas is oxygen.

3. The improved method of claim 1, wherein the known gas is carbon dioxide.

4. The improved method of claim 1, wherein the known gas is carbon monoxide.

5. The improved method of claim 1, wherein the known gas is methane.

6. An improved laser module for use in a TDL analyzer, the module defining a cavity therein across which cavity a portion of the light from a TDL is directed to collimation optics for collimating the light from the module, wherein the improvement comprises a gas reference cell positioned at least partially in the cavity so that a portion of the light from the TDL that is not directed to the collimation optics is directed through a gas in the gas reference cell to a light detector.

7. The improved laser module of claim 6, wherein the collimation optics is a positive lens.

8. The improved laser module of claim 7, further comprising a mirror positioned in the cavity for directing the portion of the light from the TDL that is not directed to the collimation optics to the gas reference cell.

9. An improved method for two point calibration of a tunable diode laser (TDL) spectrometer for the specific wavelength of light from the TDL v. the specific current fed to the TDL, for the slope of wavelength of light from the TDL v. the current fed to the TDL, to correct for any drifting of the wavelength of light from the TDL v. the specific current fed to the TDL and for any drifting of the slope of wavelength of light from the TDL v. the current fed to the TDL as the TDL ages and/or as the temperature of the TDL varies, wherein the improvement comprises the step of directing light from the TDL through a known gas and then through a gas to be analyzed to a light detector as the current fed to the TDL is varied so that current values are determined for at least two known absorption peaks of the known gas.
